(19) United States
(12) Patent Application Publication
(10) Pub. No.: US 2002/0079505 A1
(43) Pub. Date: Jun. 27, 2002

(54) Semiconductor light unit and method for production of the same

(76) Inventors: Stefan Becker, Geseke (DE); Andre Hessling-Von Heimendahl, Lippstadt (DE); Rico Schulz, Lippstadt (DE)

Correspondence Address: BIRCH STEWART KOLASCH & BIRCH, PO BOX 747, FALLS CHURCH, VA, 22040-0747, US

(21) Appl. No.: 09/791,757

(22) Filed: Feb. 26, 2001

(30) Foreign Application Priority Data
Dec. 21, 2000 (DE) 100 64 422.8

(51) Int. Cl. H01L 33/00

(52) U.S. Cl. 257/99

(57) ABSTRACT

A semiconductor light unit for vehicle optical systems, in particular aircraft. The semiconductor light unit includes a semiconductor component mounted to a substrate and electrically connected to external connections. The substrate is designed as a printed circuit board having structured printed conductors, where at least one connection of the semiconductor component can be electrically bonded on a free end of the respective printed conductor and that the respective printed conductor leads to external connections of the printed circuit board.

### BACKGROUND OF THE INVENTION

1. Field of the Invention

The present invention relates to a semiconductor light unit for vehicle optical systems, in particular in aircraft, where the semiconductor unit includes a semiconductor component mounted on a substrate and electrically connected to external connections. Moreover, the present invention relates to a method for the production of a semiconductor light unit, where a plurality of semiconductor components is added to a substrate.

2. Related Art

Light diodes are often used for the illumination in and on vehicles. Such light diodes (LED) are known, for example, from EP 0 974 485 A2. A light diode is implemented with a semiconductor component that is mounted on a carrier and potted with a plastic/synthetic material and includes an attached lens. The LED-housing formed in this manner is then electrically contacted by way of projecting connector legs on a carrier plate that is arranged inside of a light housing. The light housing generally has a light disk having a lens function on a side oriented in the direction of light emission.

A disadvantage of the known light unit is that a large construction space is required to generate a relatively large light current. Although luminescence plates are known which, similar to a plate capacitor, have a semiconductor layer between a transparent and a reflecting metal electrode, whereby the semiconductor layer can be excited to luminescence through ionization by collision, such luminescence plates are used as large-surface homogenous light sources and as display elements for large displays (see dictionary “Elektronik und Mikroelektronic” [Electronics and Microelectronics] by Dieter Sautter, Hans Weinerth, 2^{nd} edition, published by VDI in 1993, page 608).

### SUMMARY OF THE INVENTION

An object of the present invention is to provide a semiconductor light unit, and a method for the production thereof having a space-saving and high-performance light source for use in vehicles and the like.

To achieve the stated object, and additional unstated objects of the present invention, a semiconductor light unit according to the present invention includes a substrate designed as a printed circuit board having structured printed conductors, whereby at least one connection of a semiconductor component can be electrically bonded to an adjacent semiconductor component or a printed conductor and that the respective printed conductor leads to external connections of the printed circuit board.

The semiconductor light unit according to the present invention provides a simple and compact light unit with a homogenous light emission. The substrate advantageously has a double function. First, the substrate serves as a carrier for one or more semiconductor components. Second, the substrate is formed as a printed circuit board with several printed conductors. One end of the printed conductors is connected to connections of the semiconductor component and the other end of the printed conductors is connected to external connections of the printed circuit board. The external connections of the printed circuit board can be designed, for example, as contact pins that project vertically from the printed circuit board. Due to the mechanical and electrical function of the substrate according to the present invention, it is possible to obtain a light unit with minimal construction depth.

According to an embodiment of the semiconductor light unit of the present invention, the semiconductor component is designed as a chip that is connected to corresponding ends of the printed conductors by means of wire bonds. Therefore, it is advantageously possible to arrange and bond a large number of semiconductor components on a specific substrate surface. The distance between adjacent semiconductor components can be in a range of 0.3 mm to 1 mm. In this way, a relatively large packing density is achieved, which leads to a homogenous light emission. By increasing the light intensity of the semiconductor components, the number of semiconductor components may be decreased.

According to another embodiment of the semiconductor light unit, the semiconductor component is covered completely with a thermosetting casting compound. The casting compound provides mechanical protection for the semiconductor light unit.

According to a further development of the present invention, the casting compound has a conversion agent by means of which the light emitted by the semiconductor components is converted to white light. The casting compound therefore advantageously not only serves as mechanical protection, but also improves the optical properties of the semiconductor light unit.

According to a further development of the present invention, a colored filter border is added to the substrate. The filter border serves as a delimiting ring for the casting compound. Specifically, the filter border serves as a delimiting border for the semi-fluid casting compound, while it also generates a border illumination having a specific color.

According to a further development of the semiconductor light unit according to the present invention, the substrate is formed by a plurality of layers of metallic or ceramic material having low thermal resistance. Preferably, the substrate includes a thermally high-conductive material that effects a quick leakage of heat generated by the semiconductor component(s). The substrate may be comprised of rolled steel, for example.

The method according to the present invention includes several steps. In particular, a substrate is given a printed conductor structure and a plurality of semiconductor components is then mechanically connected to the substrate by means of adhesive in the provided connection areas, and connections of the semiconductor component are electrically connected to an adjacent semiconductor component or the printed conductor through wire bonds.

An advantage of the method according to the present invention is that a substrate assembled with a specific number of light-emitting semiconductor components is equipped with a structure of printed conductors that is adapted to the arrangement and number of the semiconductor components. In this way, it is possible to assemble semiconductor light units of a prescribed light strength and light surface in a simple manner.

According to a further development of the method according to the present invention, the semiconductor components are equipped with a thermosetting casting compound that encloses the same. The thermosetting casting compound is designed transparently and can also provide a mechanical protection for the light unit and has an optical lens function. Adding the casting compound with a conversion agent furthermore allows for a manipulation of the color of the light unit.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 illustrates a partial top view of a semiconductor light unit according to the present invention; and

FIG. 2 illustrates a cross-section view taken along the intersection line II-II of FIG. 1.

### DETAILED DESCRIPTION OF THE PREFERRED EMBODIMENTS

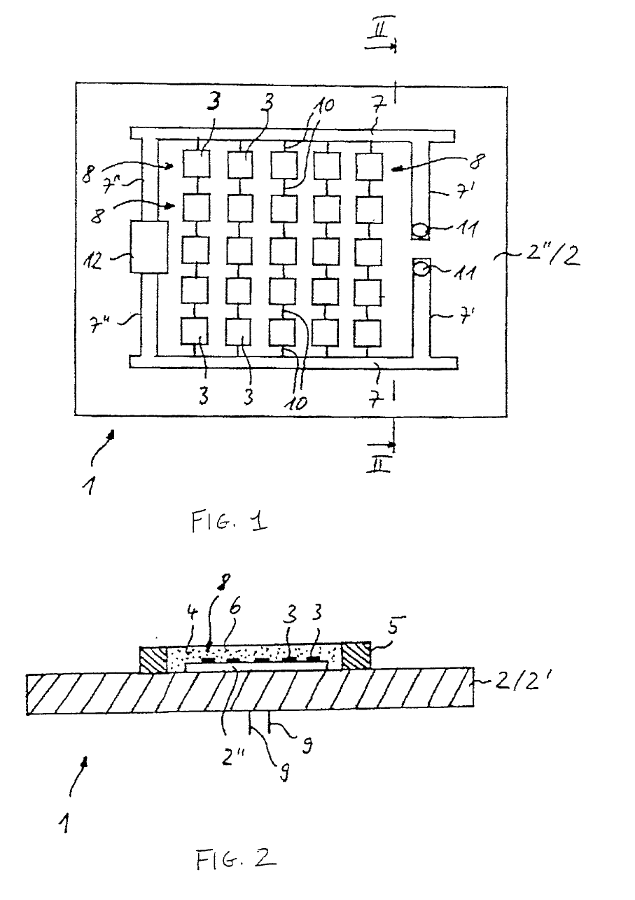

Referring to FIGS. 1 and 2, a semiconductor light unit 1 is essentially comprised of a substrate 2 on which a plurality of light-emitting semiconductor components 3 is arranged. The substrate 2 and semiconductor components 3 are covered completely with a casting compound 4.

The semiconductor components 3 are arranged evenly and at a distance of 0.3 mm to 1 mm to each other on one side of the substrate 2. However, this distance may be readily modified if such is desired. The casting compound 4 completely encloses the semiconductor components 3 and is delimited by a rigid color border 5, which projects from the substrate 2. The color border 5 effects a change of the color of the light emitted by the semiconductor components 3.

Each semiconductor component 3 is preferably designed as a chip that has electrical connections. The chip is added to the substrate 2 and adhesively connected to the same in such a manner that the electrical connections of the chip are arranged facing away from the substrate 2. Each semiconductor component 3 is comprised of a semiconductor material generally used for light diodes (LED), for example GaN or SiC. In the present embodiment, the semiconductor component 2 emits blue light in a wavelength of approximately 470 nm.

Because the casting compound 4 has a conversion agent 6, i.e., phosphorus, the blue light emitted by the semiconductor components 3 is converted into white light. The conversion agent 6 is evenly dispersed in the casting compound 4, which is comprised of silicon. In addition to mechanical protection of the semiconductor components 3 and the light-technical influence, the casting compound 4 also provides an ESD-protection that provides a rapid electrostatic discharge.

The substrate 2 is comprised of a multi-layer metallic or ceramic material, preferably a milled steel material 2′ as well as a beryllium oxide layer 2″ on which the semiconductor components 3 are arranged. To produce the semiconductor light unit 1, the substrate 2 is provided with a printed conductor structure 7 on one side. The printed conductors 7 formed in this manner can be added by etching, metallization, etc. The semiconductor components 3 are then glued to connection areas 8 of the printed circuit board prepared in this manner. Connections of the semiconductor components 3 can then be electrically connected in series by means of wire bonds through gold wires 10. The border-side semiconductor components 3 are connected through gold wires 10, or the like, to printed conductors 7 which form one respective conducting bar to which several rows of semiconductor components 3 can be bonded. The printed conductors 7 have extensions 7′ that lead to through-bonds 11. The through-bonds 11 create a connection to external connections 9, which are arranged on a side of the substrate 2 that faces away from the semiconductor components 3. The external connections 9 are designed as contact pins that can be bonded to appropriate contact elements of an electrical assembly (not shown).

The printed conductors have additional extensions 7″, which lead to a driver circuit 12 for the semiconductor components 3.

After the bonding of the semiconductor components 3 with the appropriate printed conductors 7, a complete covering of the area of a main side of the substrate 2, to which the semiconductor components 3 were added, is achieved by adding the thermosetting casting compound 4.

According to the described embodiment, the substrate 2 is equipped with 25 semiconductor components 3 that are arranged like grids. Due to the improved performance of the semiconductor components 3, the number of semiconductor components can be decreased. The construction of the semiconductor light unit 1 is simplified even more if only one single semiconductor component 3 is arranged on the substrate 2. Substrate 2 designs having greater than or less than 25 semiconductor components 3 are fully embraced by the present invention.

The semiconductor light unit 1 is used especially for the illumination of interior spaces, preferably as a reading light in aircraft. Due to the flat construction of the semiconductor light unit 1, it can be meaningfully used where little assembly space is available.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor light unit for use with vehicle optical systems, especially in aircraft, comprising:
a semiconductor component (3) mounted on a substrate and electrically connected to external connections (9), wherein the substrate (2) is a printed circuit board with structured printed conductors (7), whereby at least one connection of the semiconductor component (3) is bonded to at least one adjacent semiconductor component (3) or a printed conductor (7), and that the respective printed conductor (7) leads to the external connections (9) of the printed circuit board.

2. The semiconductor light unit according to claim 1, wherein the semiconductor component (3) is a chip and connections of the chip are connected to at least one of the adjacent semiconductor components (3) or the printed conductor (7) by means of wire bonds.

3. The semiconductor light unit according to claim 1, wherein the semiconductor component (3) is covered by a ca sting com pound (4) that comprises a conversion agent (6).

4. The semiconductor light unit according to one of the claim 3, wherein the conversion agent (6) is comprised of phosphorus, which is evenly dispersed and bonded in the casting compound (4) and converts light rays emitted by the semiconductor component (3) to light rays of a prescribed color.

5. The semiconductor light unit according to claim 3, wherein the casting compound (4) is delimited at the border by a color segment (5).

6. The semiconductor light unit according to claim 5, wherein the color segment is a rigid color border (5) for converting light rays emitted through the casting compound (4) into light rays having a specific color.

7. The semiconductor light unit according to claim 1, wherein the printed circuit board (2) has a plurality of semiconductor elements (3) that are arranged at an even distance with respect to each other.

8. The semiconductor light unit according to claim 1, wherein the adjacent semiconductor components (3) are spaced at a range of 0.3 mm to 1 mm from each other.

9. The semiconductor light unit according to claim 1, wherein the substrate (2) is comprised of a multi-layered metallic or ceramic material.

10. A method for the production of a semiconductor light unit, comprising the steps of:
adding at least one semiconductor component (3) to a substrate (2), wherein the substrate (2) has a printed conductor structure and at least one connecting area (8);
the adding step including mechanically connecting at least one semiconductor component (3) to the substrate (2) with an adhesive; and
electrically connecting connections of the semiconductor component (3) to an adjacent semiconductor component (3), or the printed conductor (7), with wire bonds.

11. The method according to claim 10, further comprising the step of applying a thermosetting transparent casting compound (4) to the at least one semiconductor component (3), whereby the casting compound (4) completely encloses free sides of the at least one semiconductor component (3).

12. The method according to claim 11, wherein the step of applying applies the thermosetting casting compound (4) to an area of the substrate (2) that is delimited by a rigid color border (5).

13. The semiconductor light unit according to claim 6, wherein the casting compound (4) is transparent.

14. The semiconductor light unit according to claim 11, wherein the at least one semiconductor component (3) is a plurality of semiconductor components (3).
